(19) United States
(12) Patent Application Publication
(10) Pub. No.: US 2026/0130094 A1
(43) Pub. Date: May 7, 2026

(54) DISPLAY DEVICE

(71) Applicant: LG Display Co., Ltd., Seoul (KR)

(72) Inventors: Hyo-Sup EUM, Seoul (KR); HeeDong LEE, Seoul (KR)

(73) Assignee: LG Display Co., Ltd., Seoul (KR)

(21) Appl. No.: 19/186,363

(22) Filed: Apr. 22, 2025

(30) Foreign Application Priority Data
Nov. 5, 2024 (KR) 10-2024-0155479

(51) Int. Cl. H10K 59/80; H10K 59/131

(52) U.S. Cl. CPC H10K 59/871; H10K 59/131; H10K 59/873; H10K 59/8794

(57) ABSTRACT

A display device according to an embodiment of the present disclosure may include a display module, a side frame configured to support a part of a lateral portion of the display module, at least one fixation part coupled to the side frame and configured to press one surface of the display module and fix the display module to the side frame. The display device further includes a connection module inserted into a rear surface of the fixation part, the connection module having a plurality of connection lines configured to electrically connect components of the display module. This structure reduces or eliminates the need for adhesives, thereby improving heat dissipation efficiency and conduction performance.

### CROSS-REFERENCE TO RELATED APPLICATIONS

This application claims the priority of Korean Patent Application No. 10-2024-0155479 filed on Nov. 5, 2024, in the Korean Intellectual Property Office, the disclosure of which is incorporated herein by reference.

### BACKGROUND

### Technical Field

The present disclosure relates to a display device including a fixing device for fixing a display module.

### Description of the Related Art

Recently, display devices, which visually display electrical information signals, are being rapidly developed in accordance with the full-scale entry into the information era. Various studies are being continuously conducted to develop a variety of display devices which are thin and lightweight, consume low power, and have improved performance.

As the representative display devices, there are a liquid crystal display device (LCD), an electrowetting display device (EWD), an organic light-emitting display device (OLED), and the like.

Among the display devices, an organic light-emitting display device refers to a display device that autonomously emits light. Unlike a liquid crystal display apparatus, the organic light-emitting display device does not require a separate light source and thus may be manufactured as a lightweight, thin display device. In addition, the organic light-emitting display device is advantageous in terms of power consumption because the electroluminescent display device operates at a low voltage. Further, the organic light-emitting display device is expected to be adopted in various fields because the organic light-emitting display device is also excellent in implementation of colors, response speeds, viewing angles, and contrast ratios (CRs).

The organic light-emitting display device is configured such that an organic light-emitting layer made of an organic material is disposed between two electrodes called an anode and a cathode. When positive holes are injected into the emission layer from the anode and electrons are injected into the emission layer from the cathode, the injected electrons and positive holes are recombined and produce excitons in an emission layer.

### BRIEF SUMMARY

Because of the spontaneous light-emitting characteristics of the organic light-emitting display device, there is a problem in that an organic light-emitting layer of a display panel is degraded, denaturized, and decomposed by heat generated from the organic light-emitting layer when the organic light-emitting display device operates over a long period of time. This degradation problem causes a luminance deviation between pixels, which causes a deterioration in image quality, such as the occurrence of an afterimage, and a decrease in lifespan. In particular, this degradation problem becomes more serious as an area of the display panel increases.

In order to solve the above-mentioned degradation problem, a heat dissipation plate, which is configured to dissipate high-temperature heat, which is generated from the display panel, to the outside, is provided between the display panel and a back cover and attached by using an adhesive tape. However, the inventors of the present disclosure have recognized that positioning a tape between the heat dissipation plate and the display panel reduces heat dissipation efficiency and causes the tape to separate due to heat generated by the display panel.

Therefore, the present disclosure provides a display device featuring a novel mechanical fixing structure that replaces traditional adhesive methods (such as tape) with a secure, modular system. The structure includes a side frame and a fixation part comprising a holder frame, holder rod, and pressing member that mechanically secure the display module components—such as the display panel, printed circuit board (PCB), and drive integrated circuits (ICs)—without the use of adhesives. This design addresses common reliability issues in OLED and similar displays by preventing component separation due to heat and improving overall structural integrity.

Additionally, various embodiments of the display device integrate an electrical connection module into the fixing structure, allowing internal components (e.g., the display panel, COF, and PCB) to be electrically connected via embedded connection lines with specially shaped contact ends. These features collectively enhance heat dissipation efficiency, reduce the risk of conductive failure, and improve the manufacturing reliability and longevity of the display device, particularly in high-performance or large-area applications.

For instance, some embodiments of the present disclosure provide a fixing device for fixing a display module, the fixing device being capable of mechanically coupling constituent elements, which constitute the display module, without using an adhesive material such as a tape, and a display device including the same.

Meanwhile, in the display module in the related art, circuit components, such as a printed circuit board or a drive integrated circuit (IC), are attached to the display panel by using a conductive tape and a chip-on-film (COF). However, there is a problem in that a tape joining defect occurs, and the COF is separated.

Some embodiments of the present disclosure provide a fixing device for fixing a display module, the fixing device being capable of tightly attaching and fastening circuit components, such as a printed circuit board or a drive IC, to a display panel without using an adhesive material such as a tape, and a display device including the same.

Technical benefits of the present disclosure are not limited to the above-mentioned benefits, and other benefits, which are not mentioned above, can be clearly understood by those skilled in the art from the following descriptions.

In order to achieve the above-mentioned benefits, a display device according to an embodiment of the present disclosure may include a display module, a side frame configured to support a part of a lateral portion of the display module, at least one fixation part coupled to the side frame and configured to press one surface of the display module and fix the display module to the side frame, and a connection module inserted into a rear surface of the fixation part and being provided with a plurality of connection lines configured to connect components of the display module.

Other detailed matters of the exemplary embodiments are included in the detailed description and the drawings.

The present disclosure may provide the display device including the fixing device of the display module that is capable of suppressing a deterioration in reliability caused by separation of an adhesive material by excluding the adhesive material, such as a tape, for fixing the constituent elements constituting the display panel.

The present disclosure may provide the display device including the fixing device of the display module, in which the heat dissipation plate, the printed circuit board, or the circuit components such as the drive IC are configured to be tightly attached directly to the display panel constituting the display module, thereby improving the heat dissipation efficiency and conduction performance and minimizing an influence on reliability affected by the surrounding environment and the operation of the display panel.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a perspective view of a display device according to a first embodiment of the present disclosure;

FIG. 2 is a cross-sectional view of the display device illustrated in FIG. 1;

FIG. 3 is a block diagram of a display module according to the first embodiment of the present disclosure;

FIG. 4 is a circuit diagram of a subpixel according to the first embodiment of the present disclosure;

FIG. 5 is a cross-sectional view of one subpixel;

FIG. 6 is a perspective view of a fixing device illustrated in FIG. 1;

FIG. 7 is an exploded perspective view of FIG. 6;

FIG. 8 is a perspective view of a side frame illustrated in FIG. 6;

FIG. 9 is an exploded perspective view of a fixation part illustrated in FIG. 6;

FIG. 10 is a perspective view of a holder frame illustrated in FIG. 9;

FIG. 11 is a perspective view illustrating a state in which the holder frame is coupled to the side frame in FIG. 8;

FIG. 12 is a cross-sectional view taken along line A-A′ in FIG. 11;

FIG. 13 is a perspective view of a pressing member illustrated in FIG. 9;

FIG. 14 is a perspective view of a buckling suppression part illustrated in FIG. 6;

FIG. 15 is a perspective view of the pressing member illustrated in FIG. 13;

FIG. 16 is a cross-sectional view illustrating the pressing member and the display module illustrated in FIG. 15;

FIG. 17 is a cross-sectional view illustrating another example of the pressing member and the display module;

FIG. 18 is a perspective view of the display device having different types of fixing devices;

FIG. 19 is a cross-sectional view of a display device according to a second embodiment of the present disclosure;

FIG. 20 is a cross-sectional view of a display device according to a third embodiment of the present disclosure; and

FIG. 21 is a cross-sectional view of a display device according to a fourth embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately”or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “in contact,” “coupled” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

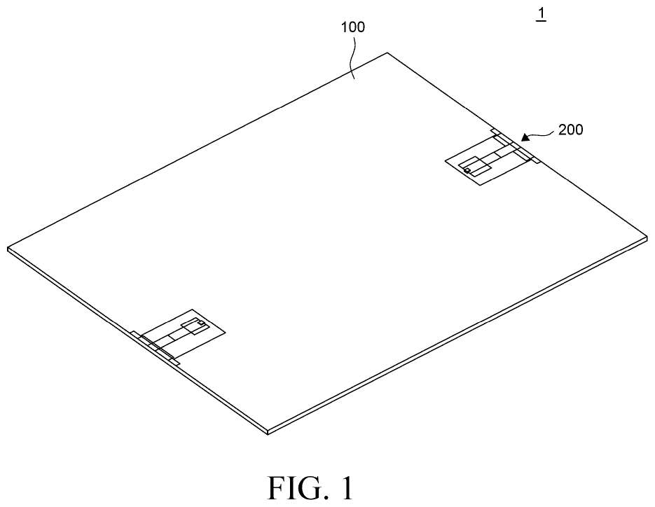

FIG. 1 is a perspective view of a display device according to a first embodiment of the present disclosure.

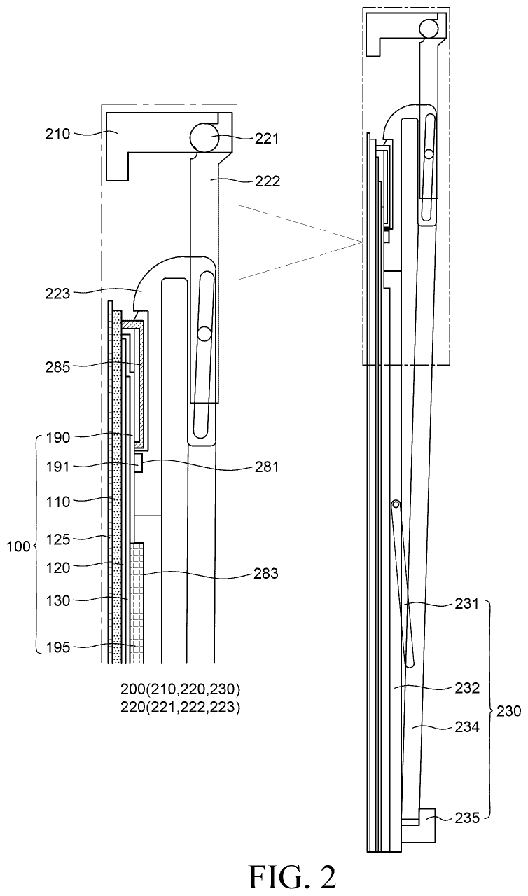

FIG. 2 is a cross-sectional view of the display device illustrated in FIG. 1.

With reference to FIGS. 1 and 2, a display device 1 of a first embodiment of the present disclosure may broadly include a display module 100 and fixing devices 200.

The display module 100 may include a display panel 110 and an encapsulation part 120 configured to cover one surface of the display panel 110.

Hereinafter, for convenience of description, a description will be described on the premise that a display surface of the display panel 110, which implements images, is directed downward based on the drawings (or leftward in FIG. 2).

Therefore, the encapsulation part 120 may be positioned above the display panel 110.

The display module 100 may further include a heat dissipation plate 130 disposed above the encapsulation part 120. An adhesive layer may be interposed between the encapsulation part 120 and the heat dissipation plate 130.

In addition, the display module 100 may further include a polarizing plate 125 disposed below the display panel 110.

As described above, the display module 100 may include the display panel 110 as an essential constituent element and selectively include the encapsulation part 120, the heat dissipation plate 130, and the polarizing plate 125. For example, the display module 100 may include the display panel 110 and the encapsulation part 120, include the display panel 110 and the heat dissipation plate 130, include the display panel 110 and the polarizing plate 125, or include all the display panel 110, the encapsulation part 120, the heat dissipation plate 130, and the polarizing plate 125.

The display panel 110 may serve to implement images and include an anode, a cathode, and organic compound layers HIL, HTL, EML, ETL, and EIL formed between the anode and the cathode. In this case, the organic compound layers may include a hole injection layer (HIL), a hole transport layer (HTL), an emission layer (EML), an electron transport layer (ETL), and an electron injection layer (EIL). When drive voltages are applied to the anode and the cathode, positive holes having passed through the hole transport layer (HTL) and electrons having passed through the electron transport layer (ETL) move to the emission layer (EML) and produce excitons, and as a result, the emission layer (EML) emits visible light. Because the display panel 110 has spontaneous light-emitting characteristics, the display panel 110 may be referred to as a spontaneous light-emitting display panel. A detailed configuration of the display panel 110 will be described below.

The encapsulation part 120 may cover one surface of the display panel 110 opposite to the display surface for implementing images. The configuration of the encapsulation part 120 may suppress an accident such as the permeation of foreign substances into the display panel 110 or damage to the display panel 110 caused by external impact.

The heat dissipation plate 130 may be disposed between the display panel 110, a COF 190, and a printed circuit board 195 and dissipate heat, which is generated while the display panel 110 and a drive IC 191 operate, to the outside. For example, the heat dissipation plate 130 may be provided in the form of a plate made of an aluminum material with excellent heat dissipation efficiency. However, the present disclosure is not limited thereto. The heat dissipation plate 130 may be selectively made of any material as long as the heat dissipation plate 130 may effectively dissipate heat generated from the display panel 110 and the drive IC 191.

The COF 190 may be disposed on the heat dissipation plate 130, extend to a top surface of the display panel 110, and be electrically connected to the display panel 110. However, the present disclosure is not limited thereto.

FIG. 2 illustrates a case in which the COF 190 is disposed on the heat dissipation plate 130. However, the present disclosure is not limited thereto. The disposition may be changed in accordance with design. That is, for example, in case that a polymer pad is disposed on the heat dissipation plate, the drive IC and the COF may be disposed on the polymer pad. In a heat dissipation structure in which a metallic material of a pressing plate, which is in contact with the drive IC, is used as a heat sink, the polymer pad may be additionally provided on the heat dissipation plate in order to improve overall thermal insulation and efficiency in heat transfer between the heat dissipation plate and the pressing plate. In contrast, in order to improve further enhanced thermal insulation, the polymer pad may be attached only to the COF, and the heat dissipation plate may be disposed only on the printed circuit board. In addition, for example, the drive IC and the heat dissipation plate may be disposed on the COF, and the printed circuit board may be disposed on the drive IC and the heat dissipation plate.

In order to suppress a decrease in contrast caused by external light, the polarizing plate 125 is positioned below the display panel 110 that transmits light.

The display module 100 improves the contrast by positioning the polarizing plate 125, which is configured to inhibit external light from being introduced from the outside, in a transmission direction of light emitted through the organic light-emitting layer in a drive mode in which the display module 100 implements images.

For example, the adhesive layer, which is transparent and has bonding properties, may be interposed between the polarizing plate 125 and the display panel 110.

The polarizing plate 125 may be a circular polarizing plate for blocking external light and include a phase difference plate and a linear polarizing plate attached to an outer surface of the display panel 110. According to the order in which the linear polarizing plate and the phase difference plate are stacked, the linear polarizing plate may be disposed to be close to an incident direction of external light, and the phase difference plate may be disposed inside the linear polarizing plate. However, the present disclosure is not limited thereto.

The phase difference plate may be configured as a quarter wave plate (QWP).

The linear polarizing plate transmits light consistent with a polarization axis and absorbs light that is not consistent with the polarization axis. Therefore, when the light passes through the linear polarizing plate, the light is linearly polarized in the direction of the polarization axis.

The fixing device 200 may include a side frame 210, a fixation part 220, and a buckling suppression part 230. The fixation part 220 may be referred to as an eccentric fixation part.

The fixation part 220 of the first embodiment of the present disclosure may include a holder frame 221 coupled to the side frame 210, a holder rod 222 coupled to the holder frame 221, and a pressing member 223 coupled to the holder rod 222 and configured to press one surface of the display module 100.

In addition, the buckling suppression part 230 may include a guide link 231, an elastic member 232, a backup member, a locking member 234, and a holder 235 and press a central portion of the fixation part 220 in one direction.

The fixing device 200 according to the first embodiment of the present disclosure may be used to mechanically fix the above-mentioned display module 100 onto the side frame 210 without using an adhesive material such as a tape.

In addition, according to the first embodiment of the present disclosure, the printed circuit board 195 and the drive IC 191 are accommodated in the fixation part 220 and coupled to the side frame 210, and the display panel 110 and the circuit components, such as the printed circuit board 195 and the COF 190, are connected by using a connection line 285 mounted on a lower portion of the fixation part 220 in a state in which the buckling suppression part 230 is tightly attached to the circuit components, such that the conduction performance and process efficiency may be improved. A detailed description thereof will be described below.

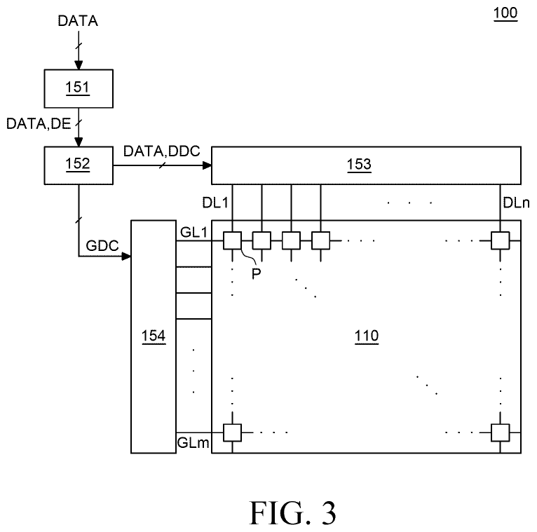

Hereinafter, a circuit configuration of the display module will be described in detail with reference to FIG. 3.

FIG. 3 is a block diagram of the display module according to the first embodiment of the present disclosure.

With reference to FIG. 3, the display module 100 according to the first embodiment of the present disclosure may include an image processor 151, a timing controller 152, a data driver 153, a gate driver 154, and the display panel 110.

The display panel 110 is a panel configured to display images to a user.

The display panel 110 may include a display element configured to display images, a driving element configured to operate the display element, and lines configured to transmit various types of signals to the display element and the driving element. Different display elements may be defined depending on the types of display panels 110. For example, in case that the display panel 110 is an organic light-emitting display panel, the display element may be an organic light-emitting element including an anode, an organic light-emitting layer, and a cathode.

Hereinafter, the assumption is made that the display panel 110 is the organic light-emitting display panel. However, the display panel 110 is not limited to the organic light-emitting display panel.

The display panel 110 may include a display area and a non-display area.

The display area is an area of the display panel 110 in which images are displayed.

The display area may include a plurality of subpixels SP constituting a plurality of pixels, and a circuit configured to operate the plurality of subpixels SP. The plurality of subpixels SP is minimum units constituting the display area. The display element may be disposed in each of the plurality of subpixels SP. The plurality of subpixels SP may constitute the pixel. For example, the light-emitting element including the anode, the organic light-emitting layer, and the cathode may be disposed on each of the plurality of subpixels SP. However, the present disclosure is not limited thereto. In addition, the circuit configured to operate the plurality of subpixels SP may include driving elements, lines, and the like.

The non-display area is an area in which no image is displayed.

Various lines and circuits for operating the light-emitting element in the display area may be disposed in the non-display area. For example, the non-display area may include link lines for transmitting signals to the plurality of subpixels and the circuit in the display area. The non-display area may include the drive IC such as a gate driver IC and a data driver IC. However, the present disclosure is not limited thereto.

Meanwhile, the left and right sides in FIG. 3 may be defined as gate pad parts on which the gate driver IC is disposed. The upper side in FIG. 3 may be defined as a data pad part connected to a flexible film. However, the present disclosure is not limited thereto.

In this case, the gate driver IC may be formed independently of the display panel 110 and electrically connected to the display panel 110 in various ways. However, the gate driver IC may be configured in a gate-in-panel (GIP) manner so as to be mounted in the display panel 110.

The display module 100 may include various additional elements configured to generate various signals or operate the plurality of subpixels SP in the display area. For example, the additional elements for operating the plurality of subpixels SP may include an inverter circuit, a multiplexer, an electrostatic discharge (ESD) circuit, and the like. The display module 100 may also include additional elements related to functions other than the function of operating the plurality of subpixels SP. For example, the display module 100 may include additional elements that provide a touch detection function, a user certification function (e.g., fingerprint recognition), a multi-level pressure detection function, a tactile feedback function, and the like. The additional elements may be positioned in the non-display area and/or an external circuit connected to a connection interface.

In addition, the flexible film may be configured to supply signals to the plurality of subpixels SP and the circuit in the display area. The flexible film may be electrically connected to the display panel 110. The flexible film is disposed at one end of the non-display area of the display panel 110. The flexible film may supply power voltage, data voltage, and other necessary signals to the plurality of subpixels SP and the circuit in the display area. For example, the drive IC such as the data driver IC may be disposed on the flexible film. With reference to FIG. 2, for example, the COF 190 may be manufactured separately from the display panel 110 and mounted on a part of the non-display area of the display panel 110, e.g., the data pad part. The COF 190 may include a plurality of circuit elements and a plurality of lines or signal lines extending from the circuit elements. One end of the line or signal line may be electrically connected to the data pad part. In addition, the printed circuit board 195 may be disposed at one end of the COF 190 and connected to the COF 190. The printed circuit board 195 is a component for supplying a signal to the drive IC 191. The printed circuit board 195 may supply various signals, such as driving signals and data signals, to the drive IC 191.

Meanwhile, the image processor 151 may output a data signal DATA, a data enable signal DE, and the like in response to the data signal DATA supplied from the outside.

The image processor 151 may output one or more of a vertical synchronizing signal, a horizontal synchronizing signal, and a clock signal in addition to the data enable signal DE.

The timing controller 152 receives the data signal DATA in addition to the data enable signal DE or the driving signals including the vertical synchronizing signal, the horizontal synchronizing signal, and the clock signal from the image processing part 151. On the basis of the driving signal, the timing controller 152 may output a gate timing control signal GDC for controlling an operation timing of the gate driver 154 and output a data timing control signal DDC for controlling an operation timing of the data driver 153.

In addition, in response to the data timing control signal DDC supplied from the timing controller 152, the data driver 153 may sample and latch the data signal DATA supplied from the timing controller 152, convert the data signal DATA into a gamma reference voltage, and output the gamma reference voltage. The data driver 153 may output the data signal DATA through data lines DL1 to DLn.

In addition, the gate driver 154 may output the gate signal while shifting a level of the gate voltage in response to the gate timing control signal GDC supplied from the timing controller 152. The gate driver 154 may output the gate signal through gate lines GL1 to GLm.

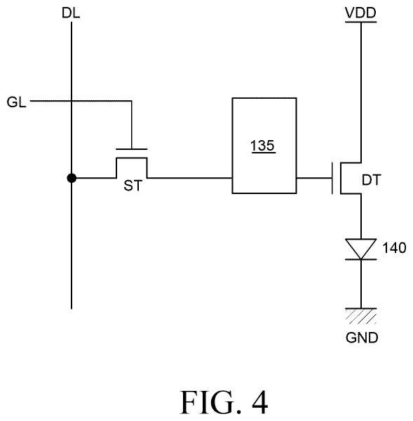

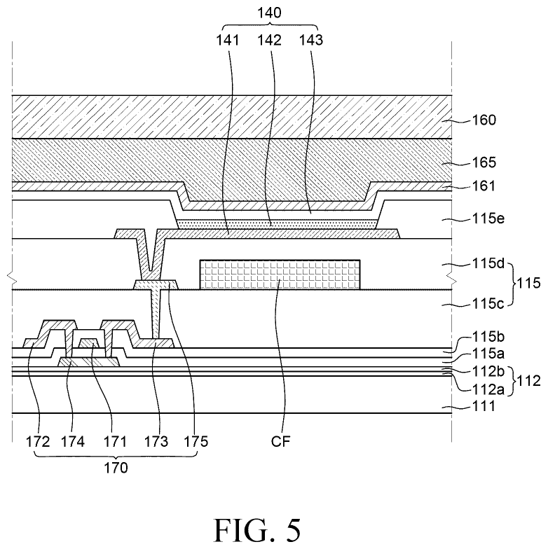

The display panel 110 may display an image as subpixels P emit light in response to the data signal DATA and the gate signal supplied from the data driver 153 and the gate driver 154. A detailed structure of the subpixel P will be described with reference to FIGS. 4 and 5.

FIG. 4 is a circuit diagram of the subpixel according to the first embodiment of the present disclosure.

With reference to FIG. 4, one subpixel according to the first embodiment of the present disclosure may include a switching transistor ST, a driving transistor DT, a compensating circuit 135, and a light-emitting element 140.

The light-emitting element 140 may operate to emit light based on a drive current produced by the driving transistor DT.

The switching transistor ST may perform a switching operation so that the data signal supplied through the data line DL is stored, as a data voltage, in a capacitor in response to the gate signal supplied through the gate line GL.

In addition, the driving transistor DT may operate such that a predetermined drive current flows between a high-potential power line VDD and a low-potential power line GND while corresponding to data voltage stored in the capacitor.

The compensating circuit 135 is a circuit for compensating for a threshold voltage or the like of the driving transistor DT. The compensating circuit 135 may include one or more thin-film transistors and one or more capacitors. The compensating circuit 135 may have very various configurations depending on a compensation method.

An example is be described in which the subpixel illustrated in FIG. 4 has a 2T(Transistor)1C(Capacitor) structure including the switching transistor ST, the driving transistor DT, the capacitor, and the light-emitting element 140. However, when the compensating circuit 135 is added, the subpixel may have various configurations such as 3T1C, 4T2C, 5T2C, 6T1C, 6T2C, 7T1C, 7T2C, or the like.

FIG. 5 is a cross-sectional view of one subpixel.

With reference to FIG. 5, a plurality of thin-film transistors 170 and the light-emitting element 140 may be disposed on an upper portion of a substrate 111.

The substrate 111 serves to support and protect constituent elements of the display panel disposed above the substrate 111.

Recently, the flexible substrate 111 may be made of a flexible material such as plastic having flexibility.

The flexible substrate 111 may be provided in the form of a film made of one selected from a group consisting of polyester-based polymer, silicon-based polymer, acrylic polymer, polyolefin-based polymer, and a copolymer thereof.

A light-blocking layer (not illustrated) may be disposed on the substrate 111.

The light-blocking layer may be made of a metallic material having a light-blocking function in order to inhibit outside light from entering a semiconductor layer 174.

For example, the light-blocking layer may be configured as a single-layer or multilayer structure made of any one of opaque metallic materials such as aluminum (Al), chromium (Cr), tungsten (W), titanium (Ti), nickel (Ni), neodymium (Nd), molybdenum (Mo), copper (Cu), and an alloy thereof.

A buffer layer 112 may be disposed on the substrate 111 on which the light-blocking layer is disposed.

For example, the buffer layer 112 is a functional layer for protecting various types of electrodes and lines from impurities, such as moisture, oxygen, or alkaline ions, introduced from the substrate 111 or a lower side. The buffer layer 112 may have a multilayer structure including a first buffer layer 112a and a second buffer layer 112b. However, the present disclosure is not limited thereto.

For example, the buffer layer 112 may be made of silicon oxide (SiOx) or silicon nitride (SiNx) or configured as a multilayer structure made of silicon oxide (SiOx) and silicon nitride (SiNx). However, the present disclosure is not limited thereto. The buffer layer 112 may be excluded depending on the types of thin-film transistors 170.

The buffer layer 112 may include a contact hole through which a part of the light-blocking layer is exposed.

The thin-film transistor 170 may be disposed above the buffer layer 112.

The thin-film transistor 170 in the display area may be a driving transistor 170. For convenience, FIG. 5 illustrates only the driving transistor 170. The display panel may also include a switching transistor, a sensing transistor, a compensating circuit, and the like.

In this case, in response to a signal received from the switching transistor, the driving transistor 170 may transmit an electric current, which is transmitted through the power line, to the anode 141. The driving transistor 170 may control light emission on the basis of the electric current transmitted to the anode 141.

To this end, the driving transistor 170 may include a gate electrode 171, the semiconductor layer 174, a source electrode 172, and a drain electrode 173.

The switching transistor is turned on by a gate pulse supplied through the gate line and transmits a data voltage, which is supplied through the data line, to the gate electrode 171 of the driving transistor 170.

The semiconductor layer 174 may be disposed on the second buffer layer 112b.

The semiconductor layer 174 may be made of polysilicon (p-Si). In this case, a predetermined area of the semiconductor layer 174 may be doped with impurities. In addition, the semiconductor layer 174 may be made of amorphous silicon (a-Si) or various organic semiconductor materials such as pentacene. Further, the semiconductor layer 174 may be made of an oxide semiconductor.

The semiconductor layer 174 may include source and drain areas including p-type or n-type impurities and a channel area between the source area and the drain area. The semiconductor layer 174 may further include a low-concentration doping area between the source and drain areas adjacent to the channel area. However, the present disclosure is not limited thereto.

The source and drain areas are areas in which impurities are doped at high concentration. The source electrode 172 and the drain electrode 173 of the thin-film transistor 170 may be respectively connected to the source and drain areas.

A gate insulation layer 115a may be disposed on the semiconductor layer 174. For example, the gate insulation layer 115a may be made of an insulating inorganic material such as silicon oxide (SiOx) or silicon nitride (SiNx). In addition, the gate insulation layer 115a may be made of an insulating organic material or the like.

The gate electrode 171 may be disposed on the gate insulation layer 115a. The gate electrode 171 may be made of various electrically conductive materials, for example, magnesium (Mg), aluminum (Al), nickel (Ni), chromium (Cr), molybdenum (Mo), tungsten (W), gold (Au), or an alloy thereof.

An interlayer insulation layer 115b may be disposed on the gate electrode 171. For example, the interlayer insulation layer 115b may be made of silicon oxide (SiOx) or silicon nitride (SiNx) or configured as a multilayer structure made of silicon oxide (SiOx) and silicon nitride (SiNx).

The source electrode 172 and the drain electrode 173 may be disposed on the interlayer insulation layer 115b.

In this case, the source electrode 172 and the drain electrode 173 may each be configured as a single layer or multilayer made of a conductive metallic material such as aluminum (Al), molybdenum (Mo), chromium (Cr), gold (Au), titanium (Ti), nickel (Ni), neodymium (Nd), copper (Cu), or an alloy thereof. However, the present disclosure is not limited thereto.

A planarization layer 115 may be disposed above the thin-film transistor 170 configured as described above. The planarization layer 115 may be an overcoat layer.

The planarization layer 115 may have a multilayer structure including at least two layers. For example, the planarization layer 115 may include a first planarization layer 115c and a second planarization layer 115d. In this case, for example, the first planarization layer 115c may be disposed to cover the thin-film transistor 170 and disposed so that a part of the drain electrode 173 of the thin-film transistor 170 is exposed.

The planarization layer 115 may have a thickness of about 2 m. However, the present disclosure is not limited thereto.

The structure of the thin-film transistor 170 may be classified into an inverted staggered structure or a coplanar structure depending on the positions of the constituent elements that constitute the thin-film transistor 170. For example, in the case of the thin-film transistor having the inverted staggered structure, the gate electrode may be positioned on a side opposite to the source electrode and the drain electrode with respect to the semiconductor layer. As illustrated in FIG. 5, in the case of the thin-film transistor 170 having the coplanar structure, the gate electrode 171 may be positioned on the same side as the source electrode 172 and the drain electrode 173 based on the semiconductor layer 174.

FIG. 5 illustrates the thin-film transistor 170 having the coplanar structure. However, the present disclosure is not limited thereto. The display device of the present disclosure may also include the thin-film transistor having the inverted staggered structure. In addition, some of the thin-film transistors 170 may have the coplanar structure, and some of the remaining thin-film transistors 170 may have the inverted staggered structure.

A connection electrode 175 may be disposed on the first planarization layer 115c and configured to electrically connect the thin-film transistor 170 and the light-emitting element 140. In addition, although not illustrated in FIG. 5, various metal layers may be disposed on the first planarization layer 115c and serve as electrodes and electric wires such as data lines or signal lines.

In addition, a color filter CF may be disposed on the first planarization layer 115c. However, the present disclosure is not limited thereto. The color filter CF may be excluded depending on the types of light-emitting elements 140.

The color filter CF of each of the subpixels may have any one of red, green, and blue colors. In addition, in the case of the subpixel that implements a white color, the color filter CF may not be disposed. The red, green, and blue colors may be variously arranged, and a black matrix capable of absorbing external light may be provided between the color filters CF.

In the case of the bottom emission type display device, the color filter CF may be positioned below the anode 141.

In addition, the second planarization layer 115d may be disposed on the first planarization layer 115c and the connection electrode 175. In the display device according to the first embodiment of the present disclosure, the configuration in which the planarization layer 115 is provided as two layers is based on the fact that the number of various types of signal lines increases as the display panel has high resolution. The additional layer is provided because it is difficult to dispose all the lines on a single layer while ensuring minimum intervals. The addition of the additional layer (the second planarization layer 115d) may provide a margin for disposing lines, which further facilitates the disposition design of lines/electrodes. Further, in case that a dielectric material is used for the planarization layer 115 having a multilayer, the planarization layer 115 may serve to create capacitance between metal layers. However, in the present disclosure, the planarization layer 115 provided as one layer may be provided.

The second planarization layer 115d may be formed such that a part of the connection electrode 175 is exposed. The drain electrode 173 of the thin-film transistor 170 and the anode 141 of the light-emitting element 140 may be electrically connected by the connection electrode 175.

The light-emitting element 140 including the anode 141, an organic layer 142, and a cathode 143 may be disposed above the second planarization layer 115d.

The anode 141 may be disposed on the second planarization layer 115d.

The anode 141 is an electrode that serves to supply positive holes to the organic layer 142. The anode 141 may be connected to the thin-film transistor 170 through a contact hole formed in the planarization layer 115.

For reference, the display device may be implemented as a top emission type or a bottom emission type. In the case of the top emission type, a reflective layer made of an opaque conductive material with high reflectance, for example, silver (Ag), aluminum (Al), gold (Au), molybdenum (Mo), tungsten (W), chromium (Cr), or an alloy thereof may be additionally disposed on a lower portion of the anode 141 so that light, which is emitted from the organic layer 142, is reflected by the anode 141 and propagates upward, i.e., in a direction toward the cathode 143 at the upper side. In contrast, in the case of the bottom emission type, the anode 141 may be made of only a transparent electrically conductive material such as indium tin oxide (ITO), indium zinc oxide (IZO), or indium gallium zinc oxide (IGZO). Hereinafter, the description will be made on the assumption that the display panel of the present disclosure is the bottom emission type.

A bank 115e may be disposed on the anode 141 and the second planarization layer 115d.

The bank 115e disposed above the anode 141 and the second planarization layer 115d may define the subpixel by dividing an area in which light is actually emitted, i.e., a light-emitting area.

A fine metal mask (FMM), which is a deposition mask, may be used to form the organic layer 142 of the light-emitting element 140. In this case, a spacer (not illustrated) may be disposed above the bank 115e and made of one of polyimide, photo acrylic, and benzocyclobutene which are transparent organic materials. The spacer is used to inhibit damage caused by contact with the deposition mask disposed on the bank 115e. The spacer serves to maintain a predetermined distance between the bank 115e and the deposition mask.

A part of the anode 141 may be exposed by removing the bank 115e in the light-emitting area.

The organic layer 142 may be disposed between the anode 141 and the cathode 143.

The organic layer 142 serves to emit light. The organic layer 142 may include at least one of a hole injection layer (HIL), a hole transport layer (HTL), an emission layer, an electron transport layer (ETL), and an electron injection layer (EIL). Some components may be excluded depending on the structure or properties of the display device.

The hole injection layer is disposed on the anode 141 and serves to facilitate the injection of the positive holes.

The hole transport layer is disposed on the hole injection layer and serves to smoothly transmit the positive holes to the emission layer.

The emission layer is disposed on the hole transport layer. The emission layer may be made of a material capable of emitting light with a particular color, thereby emitting the light with the particular color. Further, a phosphorescent material or a fluorescent material may be used as the light-emitting material.

The electron injection layer may further be disposed on the electron transport layer. The electron injection layer is an organic layer that facilitates the injection of electrons from the cathode 143. The electron injection layer may be excluded depending on the structure and properties of the display device.

Meanwhile, an electron blocking layer for blocking a flow of electrons and/or a hole blocking layer for blocking a flow of positive holes is further disposed at a position adjacent to the emission layer. Therefore, it is possible to inhibit the electron from moving from the emission layer and passing through the adjacent hole transport layer when the electrons are injected into the emission layer or inhibit the positive hole from moving from the emission layer and passing through the adjacent electron transport layer when the positive holes are injected into the emission layer, thereby improving luminous efficiency.

The cathode 143 may be disposed on the organic layer 142.

The cathode 143 may serve to supply electrons to the organic layer 142. For example, the cathode 143 needs to supply electrons. Therefore, the cathode 143 may be made of a metallic material such as magnesium, a silver-magnesium alloy, or the like that is an electrically conductive material having a low work function. However, the present disclosure is not limited thereto.

A capping layer 161 may be disposed on the cathode 143.

The capping layer 161 may serve to assist in protecting the light-emitting element 140 and efficiently discharging light, which is generated by the organic layer 142, to the outside.

An encapsulation substrate 160 may be disposed above the capping layer 161 with a bonding layer 165 interposed therebetween. However, the present disclosure is not limited thereto. An encapsulation structure configured as a multilayer structure including a sealing member and a reinforcement substrate may be disposed above the capping layer 161.

For example, the bonding layer 165 may serve to delay side moisture penetration.

For example, the bonding layer 165 may further include a moisture absorbent such as a getter in addition to isobutyl rubber resin. The moisture absorbent may include calcium oxide.

The moisture absorbent may include particles having hygroscopicity. The moisture absorbent may absorb moisture, oxygen, and the like from the outside, thereby minimizing a degree to which moisture and oxygen penetrate into the display area.

The encapsulation substrate 160 may be disposed on the bonding layer 165.

The encapsulation substrate 160, together with the bonding layer 165, may protect the light-emitting element 140 from outside moisture, oxygen, impact, and the like.

For example, the encapsulation substrate 160 may serve to suppress front moisture penetration.

For example, the encapsulation substrate 160 may be made of stainless steel (steel use stainless (SUS)) or Invar. However, the present disclosure is not limited thereto. In this case, Invar is an alloy of nickel and iron and has a very low coefficient of thermal expansion, such that Invar is relatively stable against a change in temperature.

Hereinafter, the fixing device of the present disclosure will be described in detail with reference to the drawings.

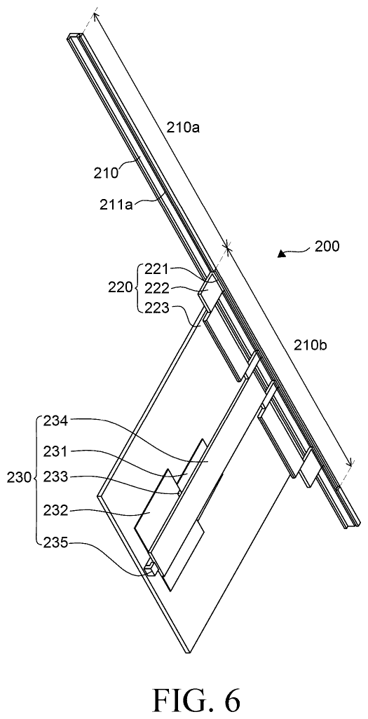

FIG. 6 is a perspective view of the fixing device illustrated in FIG. 1.

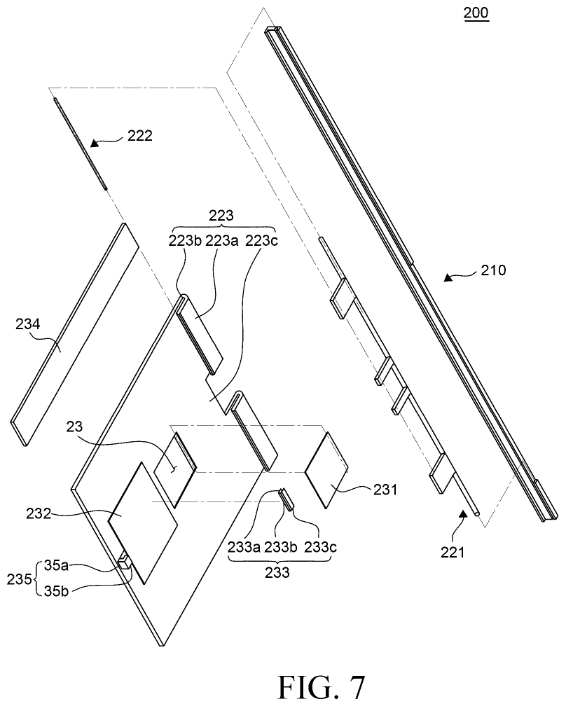

FIG. 7 is an exploded perspective view of FIG. 6.

With reference to FIGS. 6 and 7 the fixing device 200 according to the first embodiment of the present disclosure may include the side frame 210, the fixation part 220, and the buckling suppression part 230.

The side frame 210 may constitute a rim surface of the display device 1 illustrated in FIG. 1 and support a part of each lateral portion of the display module 100.

FIGS. 6 and 7 illustrate that the side frame 210 has a bar shape elongated in one direction. Finally, the side frame 210 may be formed in a ‘□’ shape having therein an opening to cover the lateral portions of the display module 100. For example, the side frame 210 may be manufactured in a ‘□’ shape by a method of providing four bars and then coupling ends of the bars. Alternatively, the side frame 210 may be manufactured in a ‘□’ shape by a method of bending a bar, which is elongated in one direction, in a ‘□’ shape and then connecting a straight frame to two opposite ends of an opened portion.

The side frame 210 may include holding parts 210a and a release part 210b configured to restrict a rotation of the fixation part 220 in accordance with a movement position of the fixation part 220.

Meanwhile, the fixation part 220 may fix the display module 100 to the side frame 210 by pressing one surface of the display module 100 on the side frame 210. The fixation part 220 may include the holder frame 221 coupled to the side frame 210, the holder rod 222 coupled to the holder frame 221, and the pressing member 223 coupled to the holder rod 222 and configured to press one surface of the display module 100.

With this configuration, the fixation part 220 may be rotatable and movable in a longitudinal direction on the side frame 210, and the rotation of the fixation part 220 may be restricted based on the movement position. For example, in case that the fixation part 220 is positioned on the holding part 210a, an upward rotation of the fixation part 220 from the side frame 210 is restricted. In contrast, in case that the fixation part 220 is positioned on the release part 210b, the fixation part 220 may rotate upward from the side frame 210. As described above, in case that the rotation of the fixation part 220 is restricted in accordance with the movement position of the fixation part 220, a lower portion and a lateral portion of the display module 100 based on the drawings are fixed by the side frame 210, and an upper portion of the fixation part 220 is fixed, such that the fixation part 220 does not separate from the side frame 210.

In case that the display module 100 is fixed onto the side frame 210 by using the fixation part 220 as described above, an adhesive material, such as a tape, for attaching the constituent elements constituting the display module 100 may be excluded. Therefore, it is possible to solve a problem of separation of the adhesive material caused by high-temperature heat generated when the display module 100 operates and a problem of thermal deformation caused by a difference in materials between the constituent elements, such that the reliability of the product may be improved. In addition, the heat dissipation plate 130 may be tightly attached directly to the display panel 110, such that the heat dissipation efficiency may be improved.

The number of fixation parts 220 may be determined depending on the size of the display module 100. That is, because a force by which the fixation part 220 presses the display module 100 may be insufficient as the area of the display module 100 increases, the number of fixation parts 220 may be selectively increased or decreased in accordance with the size of the display module 100.

The buckling suppression part 230 may be configured to press a central portion of the fixation part 220 toward the display module 100 so that the central portion of the fixation part 220 presses the display module 100. Specifically, the buckling suppression part 230 may include the guide link 231, the elastic member 232, the backup member 233, the locking member 234, and the holder 235 and press the central portion of the fixation part 220 in the downward direction based on the drawing, and a detailed description thereof will be described below.

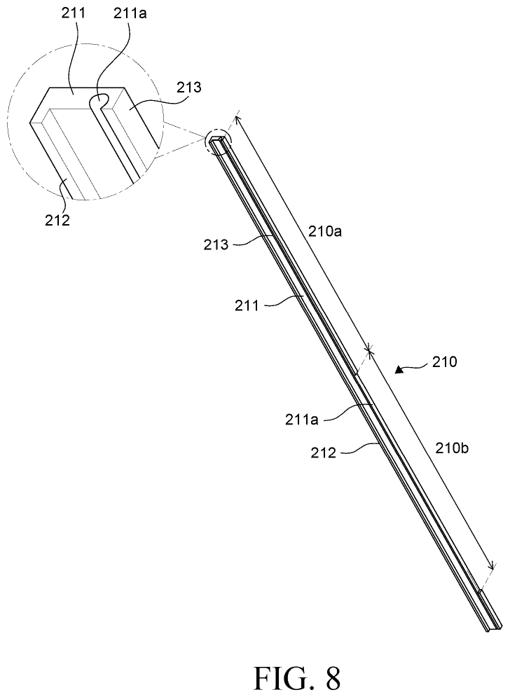

FIG. 8 is a perspective view of the side frame illustrated in FIG. 6.

With reference to FIGS. 6 and 8, the side frame 210 may include a first frame 211, a second frame 212, and rotation suppression parts 213.

The first frame 211 serves to cover a side surface of the display module 100, and a rail groove 211a may be elongated in the longitudinal direction and formed in a surface of the first frame 211 that faces the display module 100.

The second frame 212 may surround a part of the display surface of the display module 100 that implements images. The second frame 212 may extend from one end of the first frame 211 in a direction in which the display module 100 is positioned.

The rotation suppression part 213 may serve to restrict the rotation of the fixation part 220 in accordance with the movement position of the fixation part 220 and partially protrude from the side frame 210 in the direction in which the display module 100 is positioned. For example, the rotation suppression parts 213 may be provided as a plurality of rotation suppression parts 213 disposed at the other end of the first frame 211 and spaced apart from one another. A protruding end of the rotation suppression part 213 may be formed to be inclined downward in the direction in which the display module 100 is positioned.

In this case, because the side frame 210 has the rotation suppression parts 213, the side frame 210 may include the holding parts 210a on which the rotation suppression parts 213 are positioned, and the release part 210b provided between the rotation suppression parts 213. In addition, with this configuration, the fixation part 220 may rotate to the opposite side at which the display module 100 is positioned when the fixation part 220 is positioned on the release part 210b, and the rotation of the fixation part 220 may be restricted while interfering with the rotation suppression part 213 when the fixation part 220 is positioned on the holding part 210a.

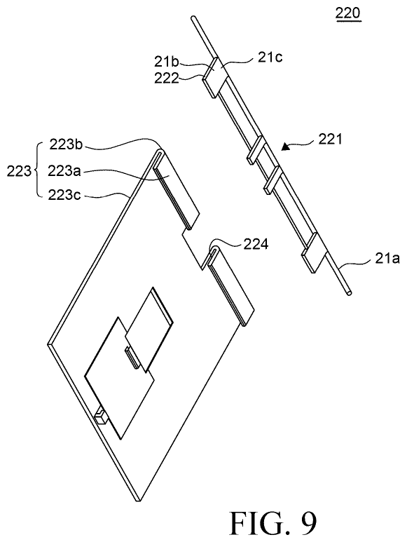

FIG. 9 is an exploded perspective view of the fixation part illustrated in FIG. 6.

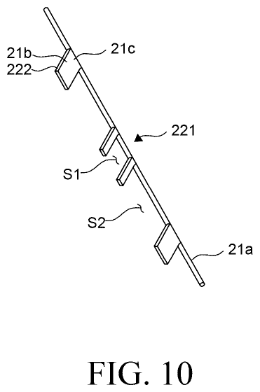

FIG. 10 is a perspective view of the holder frame illustrated in FIG. 9.

With reference to FIGS. 6, 9, and 10, the fixation part 220 may include the holder frame 221, the holder rod 222, and the pressing member 223.

The holder frame 221 may be slidably coupled to the rail groove 211a of the side frame 210. In addition, the holder frame 221 may include a rod 21a, extension plates 21b, and restriction plates 21c, and a through-hole 221a may be formed in the longitudinal direction in a lateral portion of the extension plate 21b.

The rod 21a may be slidably and movably coupled to the rail groove 211a formed in the longitudinal direction of the side frame 210. For example, the rod 21a may be formed in a cylindrical shape elongated in one direction. The rod 21a may linearly move from the rail groove 211a formed in one surface of the side frame 210 and rotate in a direction perpendicular to the linear movement direction.

The extension plates 21b may be provided as a plurality of extension plates 21b formed on a lateral portion of the rod 21a, extending in one direction, and disposed to be spaced apart from one another. For example, a total of four extension plates 21b may be provided, a pair of extension plates 21b may be disposed at a center and spaced apart from each other, and the remaining pair of extension plates 21b may be disposed outside the center and spaced apart from each other. Therefore, a first coupling space S1, to which one side of the locking member 234 to be described below is coupled, may be provided at the center, and second coupling spaces S2, to which one side of the pressing member 223 is coupled, may be provided at two opposite sides of the center. However, the present disclosure is not limited thereto.

The restriction plate 21c may protrude toward the opposite side, at which the display module 100 is positioned, from one surface of the extension plate 21b adjacent to the rod 21a and restrict the rotation of the rod 21a while interfering with a part of the side frame 210 in accordance with the rotation and movement states the rod 21a.

For example, in case that the restriction plate 21c is positioned on the release part 210b of the side frame 210 in the state in which the display module 100 is coupled to the side frame 210, the rod 21a may freely move linearly and rotate toward the opposite side at which the display module 100 is positioned. In contrast, in case that the restriction plate 21c is positioned on the holding part 210a, the restriction plate 21c interferes with a part of the side frame 210, such that the rod 21a cannot rotate any further. That is, in case that the fixation part 220 is positioned on the holding part 210a as described above, the movement of the fixation part 220 in the downward direction based on the drawings may be restricted by the extension plate 21b, and the movement of the fixation part 220 in the upward direction may be restricted by the restriction plate 21c.

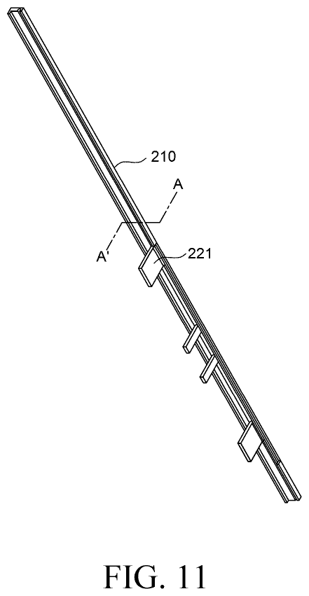

FIG. 11 is a perspective view illustrating a state in which the holder frame is coupled to the side frame in FIG. 8.

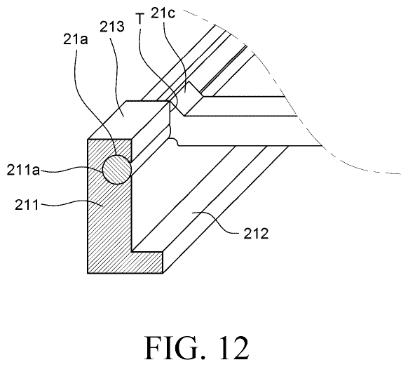

FIG. 12 is a cross-sectional view taken along line A-A′ in FIG. 11.

Meanwhile, because the holder frame 221 is in a state of being separated from the side frame 210, a force for supporting the display module 100 may be low in comparison with an integrated configuration. Therefore, as illustrated in FIG. 12, in order to improve a supporting force between the holder frame 221 and the side frame 210, a contact surface between the rotation suppression part 213 and the restriction plate 21c may be formed as an inclined surface T.

For example, the contact surface between the rotation suppression part 213 and the restriction plate 21c may be provided in a taper shape formed to be inclined downward in the direction in which the display module 100 is positioned. That is, the inclined surface T having the taper shape may increase the contact area between the rotation suppression part 213 and the restriction plate 21c, thereby improving the supporting force for supporting the display module 100. In addition, with the inclined surface T, the extension plate 21b and the fixation part 220 may move toward the display module 100 and press the display module 100. For example, an angle of the inclined surface T may be 3 to 10°. This is because it is difficult to ensure a sufficient support area when the angle of the inclined surface T is smaller than 3°, and the side frame 210 may be damaged when the angle of the inclined surface T is larger than 10°.

The holder rod 222 may be coupled to the through-hole 221a of the holder frame 221. With this configuration of the holder rod 222, the pressing member 223 and the locking member 234 to be described below may be rotatably coupled to the holder frame 221.

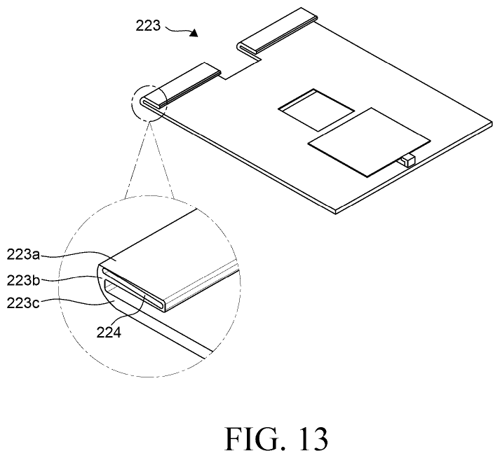

FIG. 13 is a perspective view of the pressing member illustrated in FIG. 9.

With reference to FIGS. 5, 9, and 13, a guide hole 224 may be formed through a lateral portion of the pressing member 223, and the pressing member 223 may be movably coupled to the holder frame 221 by means of the holder rod 222 inserted into the guide hole 224 and press one surface of the display module 100.

For example, the guide hole 224 formed in the lateral portion of the pressing member 223 may have a hole shape elongated from the side frame 210 toward the display module 100. Further, the guide hole 224 may be formed to be inclined downward from the side frame 210 in the direction in which the display module 100 is positioned. Therefore, when the pressing member 223 moves toward the side frame 210 along the guide hole 224 in the state in which the display module 100 is coupled to the side frame 210, a distal end portion of the pressing member 223 may press one surface of the display module 100, such that the display module 100 may be fixed between the side frame 210 and the pressing member 223.

Specifically, the pressing member 223 may include a coupling member 223a, an extension member 223b, and a pressing plate 223c.

The guide hole 224 may be provided in a lateral portion of the coupling member 223a, and the coupling member 223a may be coupled to the holder rod 222 through the guide hole 224. Therefore, in case that an external force is applied to the pressing member 223, the pressing member 223 may move along an inclination of the guide hole 224 formed in the coupling member 223a.

The extension member 223b may extend from one end of the coupling member 223a in the direction in which the display module 100 is positioned. That is, the extension member 223b may be disposed to face the first frame 211.

In addition, the pressing plate 223c may be elongated from an extending end of the extension member 223b in a perpendicular direction and selectively press the display module 100 in accordance with a change in position. That is, when the pressing member 223 moves toward the side frame 210 along the inclination of the guide hole 224 as an external force is applied to the pressing member 223, an end of the pressing plate 223c may press one surface of the display module 100 while moving downward toward the display module 100.

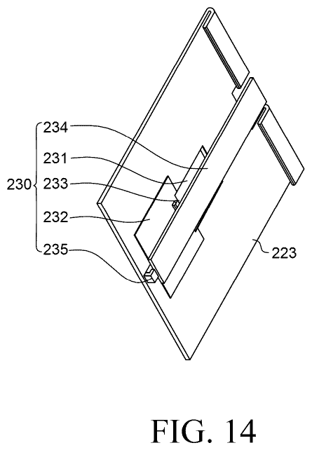

FIG. 14 is a perspective view of the buckling suppression part illustrated in FIG. 6.

With reference to FIGS. 6, 7, and 14, the buckling suppression part 230 may be configured to press the central portion of the fixation part 220 toward the display module 100 so that the central portion of the fixation part 220 presses the display module 100.

Specifically, the buckling suppression part 230 may include the guide link 231, the elastic member 232, the backup member 233, the locking member 234, and the holder 235.

The guide link 231 may be hingedly coupled to a center of the fixation part 220. For example, an opening 23 is formed by cutting a part of a central portion of the pressing plate 223c (see FIG. 5), and one side of the guide link 231 is hingedly coupled to the opening 23, such that the other side of the guide link 231 may be configured to be rotatable.

The elastic member 232 may be disposed on the fixation part 220 and face the guide link 231. When an external force is applied, the elastic member 232 may move in the direction in which the display module 100 is positioned. When the external force is eliminated, the elastic member 232 may be restored to an original position.

The elastic member 232 may be formed by cutting a part of the fixation part 220 and provided in the form of a plate including a free end configured to face the guide link 231, and a fixed end positioned at the other side of the free end. For example, one side of the elastic member 232 may be configured as the free end and the other side of the elastic member 232 may be configured as the fixed end by cutting the fixation part 220 in a ‘□’ shape, such that a thickness may gradually decreases from the fixed end in a direction in which the free end is positioned. Therefore, the elastic member 232 may be more easily transformed and restored when an external force is applied to the free end.

The backup member 233 may elastically support the other side of the guide link 231 on the elastic member 232.

For example, the backup member 233 may include a fixing plate 233a, a vertical plate 233b, and a support plate 233c.

In addition, the fixing plate 233a may be fixed to one surface of the elastic member 232 and extend from the guide link 231 in the direction in which the holder 235 is positioned. For example, the fixing plate 233a may be fixed to the free end of the elastic member 232.

The vertical plate 233b may extend from an extending end of the fixation part 220 in the perpendicular direction.

The support plate 233c may extend from the extending end of the vertical plate 233b toward the side frame 210 in the perpendicular direction. In addition, the support plate 233c may be disposed to face the fixing plate 233a and support a part of the guide link 231.

With the structures of the fixing plate 233a, the vertical plate 233b, and the support plate 233c, the backup member 233 may be provided in a ‘□’ shape and elastically support the other side of the guide link 231. In the first embodiment of the present disclosure, the backup member 233 has been illustrated and described as being formed in a ‘□’ shape. However, the structures of the backup member 233 may be variously implemented as long as the structures are elastically transformable.

For example, one side of the locking member 234 may be rotatable from the side frame 210, and a part of the other side of the locking member 234 may be supported on the guide link 231. For example, the locking member 234 may be formed in a bar shape elongated in one direction. The locking member 234 may be coupled to be rotatable by means of the holder rod 222 in the state in which one side of the locking member 234 is positioned in the first coupling space (S1 in FIG. 10).

In addition, the holder 235 may be provided on one surface of the fixation part 220 and restrict the other side of the locking member 234 when the fixation part 220 moves toward the side frame 210 to press one surface of the display module 100. For example, the holder 235 may be provided on the pressing plate 223c. When the pressing member 223 moves toward the side frame 210 along the guide hole 224, the holder 235 may surround and restrict the other side of the locking member 234 while moving toward the side frame 210 together with the pressing plate 223c. In this case, the guide link 231 and the backup member 233 are disposed below the central portion of the locking member 234 and apply pressure in the upward direction, such that the locking member 234 does not separate from the holder 235.

The holder 235 may include a first protruding member 35a and a second protruding member 35b.

The first protruding member 35a may protrude from one surface of the other side of the fixation part 220 in the perpendicular direction. Further, the second protruding member 35b may protrude from a protruding end of the first protruding member 35a in a direction in which the locking member 234 is positioned. In this case, a protruding length of the first protruding member 35a may be larger than a thickness of the locking member 234 and smaller than a total sum of thicknesses of the guide link 231, the backup member 233, and the locking member 234. This is because it is difficult to couple the locking member 234 to the holder 235 when the protruding length of the first protruding member 35a is smaller than the thickness of the locking member 234, and it is difficult to press the display module 100 by means of the elastic member 232 when the protruding length of the first protruding member 35a is larger than the total sum of thicknesses of the guide link 231, the backup member 233, and the locking member 234.

As described above, the fixing device 200 has the buckling suppression part 230, such that it is possible to press and fix not only the distal end but also the central portion of the display module 100 in the downward direction. Therefore, the deformation of the display module 100 caused by thermal expansion or vibration may be minimized, such that the display module 100 may be more stably used.

Meanwhile, as described above, in the first embodiment of the present disclosure, the printed circuit board and the drive IC are fixed to the pressing member and coupled to the side frame, the display panel and the circuit components, such as the printed circuit board and the COF, are connected by using the connection line mounted on the lower portion of the pressing member in the state in which the buckling suppression part is tightly attached to the circuit components, such that the conduction performance and process efficiency may be improved. A detailed description thereof will be described in detail.

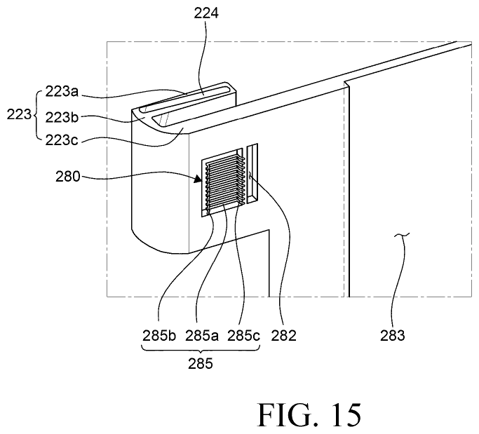

FIG. 15 is a perspective view of the pressing member illustrated in FIG. 13.

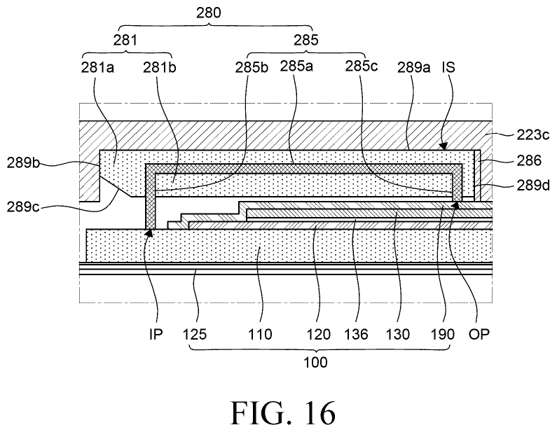

FIG. 16 is a cross-sectional view illustrating the pressing member and the display module illustrated in FIG. 15.

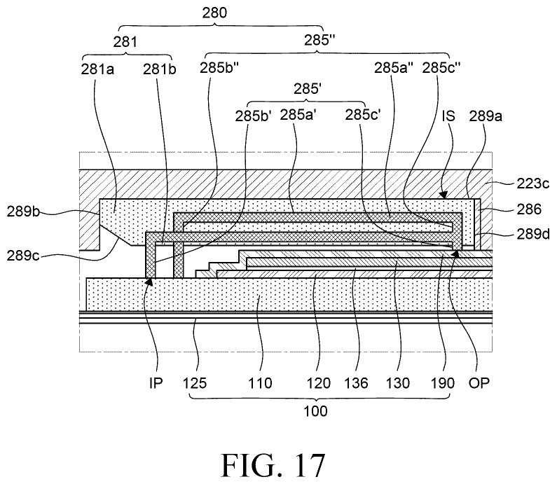

FIG. 17 is a cross-sectional view illustrating another example of the pressing member and the display module.

FIG. 15 is a perspective view illustrating a rear surface of the pressing member illustrated in FIG. 13.

In addition, FIGS. 16 and 17 are views illustrating the pressing member illustrated in FIG. 15 and illustrating a part of a cross-section of the display module coupled to the pressing member.

With reference to FIGS. 2, 13, 15, and 16 together, the display device of the first embodiment of the present disclosure may broadly include the display module 100 and the fixing device 200.

As described above, the display module 100 may include the display panel 110 and the encapsulation part 120 configured to cover one surface of the display panel 110.

The display module 100 may further include the heat dissipation plate 130 disposed above the encapsulation part 120. An adhesive layer 136 may be interposed between the encapsulation part 120 and the heat dissipation plate 130.

In addition, the display module 100 may further include the polarizing plate 125 disposed below the display panel 110.

The fixing device 200 may include the side frame 210, the fixation part 220, and the buckling suppression part 230.

In this case, the fixation part 220 may include the holder frame 221 coupled to the side frame 210, the holder rod 222 coupled to the holder frame 221, and the pressing member 223 coupled to the holder rod 222 and configured to press one surface of the display module 100.

As described above, the pressing member 223 may include the coupling member 223a, the extension member 223b, and the pressing plate 223c.

The guide hole 224 may be provided in the lateral portion of the coupling member 223a, and the coupling member 223a may be coupled to the holder rod 222 through the guide hole 224. Therefore, in case that an external force is applied to the pressing member 223, the pressing member 223 may move along the inclination of the guide hole 224 formed in the coupling member 223a.

The extension member 223b may extend from one end of the coupling member 223a in the direction in which the display module 100 is positioned.

In addition, the pressing plate 223c may be elongated from the extending end of the extension member 223b in the perpendicular direction and selectively press the display module 100 in accordance with a change in position. That is, when the pressing member 223 moves toward the side frame 210 along the inclination of the guide hole 224 as an external force is applied to the pressing member 223, the end of the pressing plate 223c may press one surface of the display module 100 while moving downward toward the display module 100.

Meanwhile, the fixation part 220 may serve not only to press and fix the display module 100 but also to accommodate and fix the circuit components, such as the drive IC 191 and the printed circuit board 195, and electrically connect the circuit components to the display module 100. The present disclosure may include at least one of the fixing device 200 configured to play the former role and the fixing device 200 configured to play the latter role or include the fixing device 200 configured to play both the former role and the latter role.

The number of drive ICs 191 and the number of printed circuit boards 195 may be determined depending on the size of the display panel 110. An appropriate number of fixing devices 200 may be provided to fix the drive IC 191 and the printed circuit board 195 to the side frame 210.

According to the first embodiment of the present disclosure, the printed circuit board 195 and the drive IC 191 may be accommodated in the fixation part 220 and coupled to the side frame 210. To this end, a first accommodation groove 282 configured to accommodate the drive IC 191 and a second accommodation groove 283 configured to accommodate the printed circuit board 195 may be provided in a rear surface of the pressing member 223 according to the first embodiment of the present disclosure. Therefore, for example, the drive IC 191 may be accommodated in the first accommodation groove 282 of the pressing member 223, and the printed circuit board 195 may be accommodated and fixed in the second accommodation groove 283 of the pressing member 223. Therefore, the conduction performance and process efficiency may be improved.

For example, the first accommodation groove 282 and the second accommodation groove 283 may be disposed in the rear surface of the pressing member 223 and spaced apart from each other.

The first accommodation groove 282 may have an accommodation space having a shape corresponding to the drive IC 191, and the second accommodation groove 283 may have an accommodation space having a shape corresponding to the printed circuit board 195. That is, for example, the first accommodation groove 282 may have an accommodation space having a depth and an area corresponding to a height and an area of the drive IC 191, and the second accommodation groove 283 may have an accommodation space having a depth and an area corresponding to a height and an area of the printed circuit board 195.

The number of first accommodation groove 282 may correspond to the number of drive ICs 191, and the number of second accommodation grooves 283 may correspond to the number of printed circuit boards 195.

However, the present disclosure is not limited to the above-mentioned configuration. In case that the drive IC 191 is mounted on the printed circuit board 195, the pressing member 223 may have one accommodation groove configured to accommodate the printed circuit board 195 and the drive IC 191 together.

FIG. 15 illustrates a case in which the first accommodation groove 282 is positioned leftward of the second accommodation groove 283. For example, the first accommodation groove 282 may be positioned to be closer to the extension member 223b than the second accommodation groove 283 to the extension member 223b. However, the present disclosure is not limited thereto.

In case that the printed circuit board 195 is disposed leftward of the drive IC 191, the second accommodation groove 283 may be positioned to be closer to the extension member 223b than the first accommodation groove 282 to the extension member 223b. That is, the first accommodation groove 282 and the second accommodation groove 283 may be positioned while corresponding to the drive IC 191 and the printed circuit board 195.

Meanwhile, a connection module 280, in which a plurality of connection lines 285 are mounted, may be inserted into the rear surface of the pressing member 223, specifically, the rear surface of the pressing plate 223c. For example, the connection module 280 may be positioned to be closer to the extension member 223b than the first accommodation groove 282 to the extension member 223b. However, the present disclosure is not limited thereto. For example, the connection module 280 may be inserted into the rear surface of the pressing plate 223c corresponding to the coupling member 223a. However, the present disclosure is not limited thereto.

The connection module 280 of the first embodiment of the present disclosure may include a filling layer 281, and the plurality of connection lines 285 disposed in the filling layer 281.

For example, the connection module 280 may include a bottom surface 289a having an approximately rectangular flat surface shape, and sidewalls 289b perpendicularly extending from the bottom surface 289a.

The sidewalls 289b may constitute support portions for supporting the connection module 280.

The sidewall 289b, which is adjacent to the extension member 223b among the sidewalls 289b, may constitute a guide portion 289c inclined inward.

The sidewall, which is opposite to the guide portion 289c among the sidewalls 289b, may constitute an elastic portion 289d. For example, an elastic member 286, such as a pad, may be interposed between the elastic portion 289d and the pressing plate 223c.

In case that the guide portion 289c extends from the vertical sidewall 289b and is inclined inward, the guide portion 289c may serve as a suppression projection.

An insertion space IS, into which the connection module 280 is fitted and inserted, may be provided in the rear surface of the pressing plate 223c. For example, when the connection module 280 is fitted and inserted into the insertion space IS in the rear surface of the pressing plate 223c, the elastic member 286 may serve to suppress the separation while interacting with the guide portion 289c having a wedge shape by using an elastic force and mitigate the restriction caused by thermal expansion while the display device operates. An electrical conduction suppression coating may be provided in the insertion space IS in the rear surface of the pressing plate 223c.

Meanwhile, when the connection module 280 is inserted into the insertion space IS in the rear surface of the pressing plate 223c, the connection module 280 may be pressed along the guide portion 289c and fixed at a position at which equilibrium of forces between the sidewall 289b and the elastic portion 289d of the guide portion 289c is implemented.

In addition, the connection lines 285 may include wiring portions 285a arranged side by side in one direction, and contact portions 285b and 285c extending from ends of the wiring portions 285a in the perpendicular direction. For example, the connection line 285 may connect a pad IP of the display panel 110 and an output pad OP of the COF 190.

To this end, the wiring portions 285a may be arranged side by side in one direction between the pad IP of the display panel 110 and the output pad OP of the COF 190.

For reference, the COF 190 has a shape in which the drive IC 191 is mounted directly on a film.

A main connection portion of the COF 190 may be the output pad OP. The output pad OP may serve to transmit signals, which are outputted from channels of the drive IC 191, to the data line and/or the gate line of the display panel 110 through the pad IP of the display panel 110.

The connection portion of the display panel 110 is gate and source pads IP.

The pads IP may be positioned at an edge of the display panel 110, and the pads IP may be disposed in a direction parallel to the output pad OP of the COF 190.

The connection line 285 may include a first contact portion 285b extending from an end of the wiring portion 285a in the perpendicular direction and connected to the pad IP of the display panel 110, and a second contact portion 285c extending from an end of the wiring portion 285a in the perpendicular direction and connected to the output pad OP of the COF 190. When the fixation part 220 presses the display module 100, the pad IP of the display panel 110 and the first contact portion 285b are connected and the output pad OP of the COF 190 and the second contact portion 285c are connected by means of the inclined end of the first contact portion 285b and the inclined end of the second contact portion 285c.

Meanwhile, the first contact portion 285b and the second contact portion 285c may be configured as an inclined type or a “J” type so as to be easily and electrically connected to the pad IP of the display panel 110 and the output pad OP of the COF 190.

For example, the inclined type has a structure (an inclined structure) having an inclined end and is designed such that contact points or electrode parts of the contact portions 285b and 285c are inclined at predetermined angles so as to be easily connected electrically. Because the pad IP of the display panel 110 or the output pad OP of the COF 190 is obliquely connected, a larger contact area may be ensured when the components are connected. The increase in contact area may improve the stability of the electrical connection and reduce resistance and a loss of electricity. In addition, the components may be easily disposed in the vertical or horizontal direction when being installed and easily combined with various devices.

Further, the “J” type has a structure having an alphabet “J” shape and is designed such that ends of the contact portions 285b and 285c may be curved in “J” shapes and flexibly disposed on the connection portions. The curved “J” shape may improve installation flexibility because lines may be installed in various directions when electrical connection is required at a particular angle. The curved “J” shape may reduce an installation space in comparison with a general rectilinear structure, which is advantageous in configuring electrical connection in a limited space. In addition, the structure of the “J” shape increases the mechanical strength and implements relatively excellent resistance against vibration or impact.

The above-mentioned connection implemented by the contact portions 285b and 285c of the connection module 280 may suppress a problem of a joining defect caused by the use of a conductive tape or a problem of separation caused by the use of a COF.

According to the first embodiment of the present disclosure, in the state in which the buckling suppression part 230 is tightly attached to the circuit components such as the printed circuit board 195 and the COF 190, the pad IP of the display panel 110 and the output pad OP of the COF 190 may be connected by using the connection module 280 mounted on the rear surface of the pressing plate 223c, thereby improving the conduction performance. In addition, a conductive tape may be removed, which may minimize an influence on reliability affected by the surrounding environments and the operation of t display device.

Meanwhile, the filling layer 281 may be made of resin. For example, the filling layer 281 may include a first filling layer 281a positioned relatively inward based on the connection line 285, and a second filling layer 281b positioned relatively outward based on the connection line 285. However, the present disclosure is not limited thereto. In this case, the first filling layer 281a and second filling layer 281b may be configured to surround the connection lines 285, except for the ends of the contact portions 285b and 285c at the two opposite sides.

For example, the filling layer 281 may be manufactured by insert-molding. However, the present disclosure is not limited thereto.

For reference, the insert molding is one of the injection molding processes and refers to a process method of producing an integrated product by disposing a previously processed component (insert) in a mold and injecting resin (plastic) around the component (insert). Because this process performs the injection after inserting the component, which is manufactured outside, into the mold, unlike general injection molding, there is an advantage in coupling components made of various materials into a single component.

For example, the first filling layer 281a is formed by using injection molding or the like. In this case, a pattern having a groove shape, into which the connection line 285 may be fitted and inserted, is formed on a top surface of the first filling layer 281a. Next, the integrated filling layer 281 is formed by fitting and inserting the connection lines 285 into the pattern of the groove shape of the first filling layer 281a and then forming a second filling layer 281b by injecting resin around the connection lines 285.

Meanwhile, with reference to FIG. 17, according to another example of the first embodiment of the present disclosure, the connection module 280, in which a plurality of connection lines 285′ and 285″ are mounted, may be inserted into the rear surface of the pressing plate 223c.

For example, the plurality of connection lines 285′ and 285″ may include first connection lines 285′ and second connection lines 285″ having different lengths.

The first connection lines 285′ may include first wiring portions 285a′ arranged side by side in one direction, and first contact portions 285b′ and 285c′ extending from ends of the first wiring portions 285a′ in the perpendicular direction.

For example, the first connection line 285′ may include a first-first contact portion 285b′ extending from an end of the first wiring portion 285a′ in the perpendicular direction and connected to the display panel 110, and a first-second contact portion 285c′ extending from an end of the first wiring portion 285a′ in the perpendicular direction and connected to the COF 190.

The second connection lines 285″ may include second wiring portions 285a″ arranged side by side in one direction, and second contact portions 285b″ and 285c″ extending from ends of the second wiring portions 285a″ in the perpendicular direction.

For example, the second connection line 285″ may include a second-first contact portion 285b″ extending from an end of the second wiring portion 285a″ in the perpendicular direction and connected to the display panel 110, and a second-second contact portion 285c″ extending from an end of the second wiring portion 285a″ in the perpendicular direction and connected to the COF 190.

For example, the first wiring portion 285a′ may have a longer length than the second wiring portion 285a″. However, the present disclosure is not limited thereto. In this case, the second contact portions 285b″ and 285c″ may have a longer length than the first contact portions 285b′ and 285c′ so that a total resistance value between the first connection line 285′ and the second connection line 285″ does not change. However, the present disclosure is not limited thereto.

FIG. 17 illustrates an example in which the first-first contact portion 285b′ is positioned forward of the second-first contact portion 285b″. However, the present disclosure is not limited thereto. The second-first contact portion 285b″ may be positioned forward of the first-first contact portion 285b′.

Meanwhile, the fixation part configured to press and fix the display module and the fixation part configured to accommodate and fix the circuit components and electrically connect the circuit components to the display module may be combined and applied, and this configuration will be described with reference to the drawings.

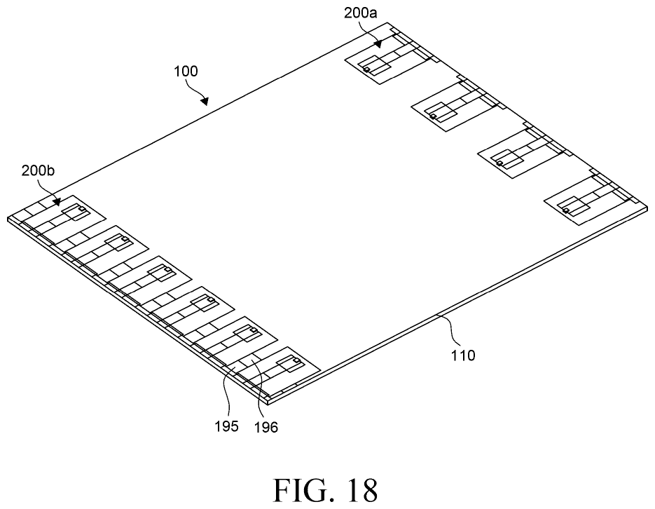

FIG. 18 is a perspective view of the display device having different types of fixing devices.

The display device in FIG. 18 is substantially identical in configuration to the display device in FIGS. 1 to 16, except that different types of fixing devices 200a and 200b are combined and applied. Therefore, repeated descriptions of the identical components will be omitted.

Hereinafter, the components denoted by the same reference numerals will be described with reference to FIGS. 1 to 18.

With reference to FIG. 18, the display device may broadly include the display module 100 and the fixing devices 200a and 200b.

The display module 100 may include the display panel 110 and the encapsulation part configured to cover one surface of the display panel 110.

The printed circuit board 195 may be disposed above one side of the display panel 110, and a heat dissipation sheet 196 configured to cover a part of the printed circuit board 195 may be disposed above the printed circuit board 195.

Meanwhile, a plurality of second fixing devices 200b may be disposed above one side of the display panel 110 on which the printed circuit board 195 is disposed, and a plurality of first fixing devices 200a may be disposed above the other side of the display panel 110. FIG. 18 illustrates a case in which six second fixing devices 200b are disposed above one side of the display panel 110 and four first fixing devices 200a are disposed above the other side of the display panel 110. However, the present disclosure is not limited to the number of first and second fixing devices 200a and 200b. In addition, first fixing device 200a may be disposed above three portions of the display panel 110, except for the upper portion of one side of the display panel 110 on which the printed circuit board 195 is disposed. In addition, the first fixing device 200a may be disposed between the second fixing devices 200b.

The number of drive ICs and the number of printed circuit boards 195 may be determined depending on the size of the display panel 110. An appropriate number of second fixing devices 200b may be provided to fix the drive IC and the printed circuit board 195 to the side frame.

The second fixing device 200b is substantially identical in configuration to the first fixing device 200a, except that the first and second accommodation grooves configured to accommodate the drive IC and the printed circuit board 195 are provided, and the connection module in which the plurality of connection lines are mounted is provided.

As described above, the first fixing device 200a and the second fixing device 200b may include the side frames, the fixation parts, and the buckling suppression parts. In addition, the fixation part may include the holder frame coupled to the side frame, the holder rod coupled to the holder frame, and the pressing member coupled to the holder rod and configured to press one surface of the display module.

The first fixing device 200a and the second fixing device 200b may be used to mechanically fix the above-mentioned display module 100 onto the side frame without using an adhesive material such as a tape.

In addition, a plurality of first accommodation grooves configured to accommodate the drive IC and a plurality of second accommodation grooves configured to accommodate the printed circuit board 195 may be provided in the rear surface of the pressing member of the second fixing device 200b.

In addition, a plurality of connection modules, in which the plurality of connection lines are mounted, may be provided in the rear surface of the pressing member of the second fixing device 200b.

Meanwhile, as described above, according to the present disclosure, the connection module may be used to electrically connect the display panel and the COF. However, the present disclosure is not limited thereto. The COF and the printed circuit board may be electrically connected in a state in which the COF and the printed circuit board are bonded to the display panel. In case that the drive IC is mounted on the display panel, the display panel and the printed circuit board may be electrically connected. This configuration will be described in detail with reference to the drawings.

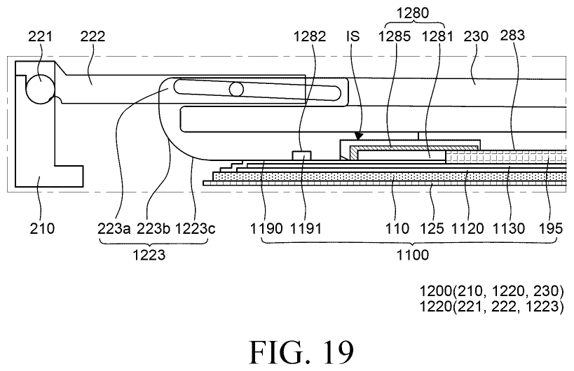

FIG. 19 is a cross-sectional view of a display device according to a second embodiment of the present disclosure.

The second embodiment in FIG. 19 is substantially identical in configuration to the above-mentioned first embodiment illustrated in FIGS. 1 to 17, except for a connection relationship between the circuit components using a connection module 1280. Therefore, repeated descriptions of the identical components will be omitted. Hereinafter, the components denoted by the same reference numerals will be described with reference to FIGS. 1 to 18.

With reference to FIG. 19, the display device of the second embodiment of the present disclosure may broadly include a display module 1100 and fixing devices 1200.

The display module 1100 may include the display panel 110 and an encapsulation part 1120 configured to cover one surface of the display panel 110.

The encapsulation part 1120 of the second embodiment of the present disclosure may further extend to the end of the display panel 110 in comparison with that in the above-mentioned first embodiment. However, the present disclosure is not limited thereto.

The display module 1100 may further include a heat dissipation plate 1130 disposed above the encapsulation part 1120. The heat dissipation plate 1130 of the second embodiment may further extend to the end of the display panel 110 in comparison with that in the above-mentioned first embodiment. However, the present disclosure is not limited thereto.

An adhesive layer may be interposed between the encapsulation part 1120 and the heat dissipation plate 1130.

The polarizing plate 125 may be disposed below the display panel 110.

In addition, a COF 1190 and the printed circuit board 195 may be disposed above the heat dissipation plate 1130. The COF 1190 may be disposed outward of the printed circuit board 195. That is, the COF 1190 may be disposed to be closer to the end (end part) of the display panel 110 than the printed circuit board 195 to the end (end part) of the display panel 110. The COF 1190 may be disposed on the heat dissipation plate 1130, extend to the top surface of the display panel 110, and be electrically connected to the display panel 110. However, the present disclosure is not limited thereto.

A Drive IC 1191 May Be Mounted on the COF 1190.

As described above, the fixing device 1200 may include the side frame 210, a fixation part 1220, and the buckling suppression part 230.

The fixation part 1220 of the second embodiment of the present disclosure may include the holder frame 221 coupled to the side frame 210, the holder rod 222 coupled to the holder frame 221, and a pressing member 1223 coupled to the holder rod 222 and configured to press one surface of the display module 1100. The fixation part 1220 may fix the display module 1100 to the side frame 210 by pressing one surface of the display module 1100 on the side frame 210.

The fixing device 1200 of the second embodiment of the present disclosure may be used to mechanically fix the display module 1100 onto the side frame 210 without using an adhesive material such as a tape. Therefore, it is possible to solve a problem of separation of the adhesive material caused by high-temperature heat generated when the display module 1100 operates, such that the reliability of the product may be improved. In addition, the heat dissipation plate 1130 may be tightly attached directly to the display panel 1110, such that the heat dissipation efficiency may be improved.

The number of fixation parts 1220 may be determined depending on the size of the display module 1100.

As described above, the pressing member 1223 may include the coupling member 223a, the extension member 223b, and a pressing plate 1223c.

In this case, the pressing plate 1223c may be elongated from the extending end of the extension member 223b in the perpendicular direction and selectively press the display module 1100 in accordance with a change in position.

According to the second embodiment of the present disclosure, the printed circuit board 195 and the drive IC 1191 may be accommodated in the fixation part 1220 and coupled to the side frame 210. To this end, a first accommodation groove 1282 configured to accommodate the drive IC 1191 and the second accommodation groove 283 configured to accommodate the printed circuit board 195 may be provided in the rear surface of the pressing member 1223 according to the second embodiment of the present disclosure. For example, the drive IC 1191 may be accommodated in the first accommodation groove 1282 of the pressing member 1223, and the printed circuit board 195 may be accommodated and fixed in the second accommodation groove 283 of the pressing member 1223. Therefore, the conduction performance and process efficiency may be improved. However, the present disclosure is not limited thereto. The second accommodation groove 283 may not be provided in case that a space required to fasten or separate the fixing device 200 is not sufficient.

For example, the first accommodation groove 1282 and the second accommodation groove 283 may be disposed in the rear surface of the pressing member 1223 and spaced apart from each other.

The first accommodation groove 1282 may have an accommodation space having a shape corresponding to the drive IC 1191, and the second accommodation groove 283 may have an accommodation space having a shape corresponding to the printed circuit board 195. For example, the first accommodation groove 1282 may have an accommodation space having a depth and an area corresponding to a height and an area of the drive IC 1191, and the second accommodation groove 283 may have an accommodation space having a depth and an area corresponding to a height and an area of the printed circuit board 195.

The number of first accommodation groove 1282 may correspond to the number of drive ICs 1191, and the number of second accommodation grooves 283 may correspond to the number of printed circuit boards 195.

For example, the first accommodation groove 1282 may be positioned to be closer to the extension member 223b than the second accommodation groove 283 to the extension member 223b. However, the present disclosure is not limited thereto. The first accommodation groove 1282 and the second accommodation groove 283 may be positioned while corresponding to the drive IC 1191 and the printed circuit board 195.

Meanwhile, the connection module 1280, in which a plurality of connection lines 1285 are mounted, may be inserted into the rear surface of the pressing plate 1223c. For example, the connection module 1280 of the second embodiment may be positioned between the first accommodation groove 1282 and the second accommodation groove 283. However, the present disclosure is not limited thereto. In addition, a part of the connection module 1280 may overlap the printed circuit board 195.

The connection module 1280 of the second embodiment of the present disclosure may include a filling layer 1281, and the plurality of connection lines 1285 disposed in the filling layer 1281.

An insertion space IS, into which the connection module 1280 is fitted and inserted, may be provided in the rear surface of the pressing plate 1223c. The insertion space IS may partially overlap the second accommodation groove 283. That is, a part of the insertion space IS may constitute the second accommodation groove 283.

Meanwhile, the connection line 1285 of the second embodiment of the present disclosure may connect the COF 190 and the printed circuit board 195.

As described above, the connection line 1285 may include a contact portion extending from an end of the wiring portion in the perpendicular direction and connected to the COF 190 and the printed circuit board 195. In this case, the contact portion may be configured as an inclined type or a “J” type.

The above-mentioned connection implemented by the contact portion of the connection module 1280 may suppress a problem of a joining defect caused by the use of a conductive tape or a problem of separation caused by the use of a COF.

According to the second embodiment of the present disclosure, in the state in which the buckling suppression part 230 is tightly attached to the circuit components such as the printed circuit board 195 and the COF 1190, the COF 190 and the printed circuit board 195 may be connected by using the connection module 1280 mounted on the rear surface of the pressing plate 1223c, thereby improving the conduction performance. In addition, a conductive tape may be removed, which may minimize an influence on reliability affected by the surrounding environments and the operation of t display device.

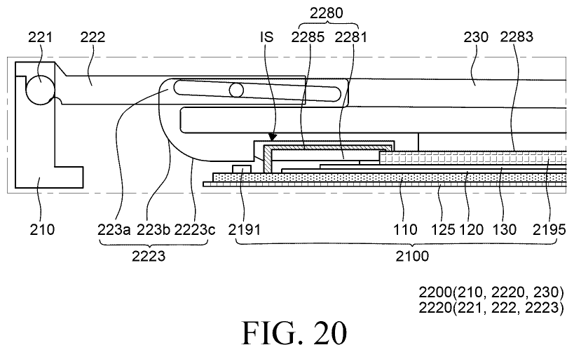

FIG. 20 is a cross-sectional view of a display device according to a third embodiment of the present disclosure.

The third embodiment in FIG. 20 is substantially identical in configuration to the above-mentioned first embodiment illustrated in FIGS. 1 to 17, except for a connection relationship between the circuit components using a connection module 2280. Therefore, repeated descriptions of the identical components will be omitted. Hereinafter, the components denoted by the same reference numerals will be described with reference to FIGS. 1 to 19.

With reference to FIG. 20, the display device of the third embodiment of the present disclosure may broadly include a display module 2100 and fixing devices 2200.

The display module 2100 may further include the display panel 110, the encapsulation part 120 configured to cover one surface of the display panel 110, and the heat dissipation plate 130 disposed above the encapsulation part 120.

The polarizing plate 125 may be disposed below the display panel 110.

Meanwhile, in the third embodiment of the present disclosure, a drive IC 2191 may be mounted on the display panel 110. Therefore, the COF may be excluded, unlike the above-mentioned first and second embodiments.

In addition, a printed circuit board 2195 may be disposed above the heat dissipation plate 130. In the third embodiment of the present disclosure, because the COF is excluded, the printed circuit board 2195 may be disposed to be closer to the end of the display panel 110, in comparison with the above-mentioned first and second embodiments.

As described above, the fixing device 2200 may include the side frame 210, a fixation part 2220, and the buckling suppression part 230. A pressing member 2223 may include the coupling member 223a, the extension member 223b, and a pressing plate 2223c.

According to the third embodiment of the present disclosure, the printed circuit board 2195 may be accommodated in the fixation part 2220 and coupled to the side frame 210. To this end, a second accommodation groove 2283 configured to accommodate the printed circuit board 2195 may be provided in a rear surface of the pressing member 2223 according to the third embodiment of the present disclosure.

In this case, the second accommodation groove 2283 may have an accommodation space having a shape corresponding to the printed circuit board 2195. For example, the second accommodation groove 2283 may have an accommodation space having a depth and an area corresponding to a height and an area of the printed circuit board 2195.

Meanwhile, the connection module 2280, in which a plurality of connection lines 2285 are mounted, may be inserted into the rear surface of the pressing plate 2223c. For example, the connection module 2280 of the third embodiment may be positioned to be close to an extension member 2223b than the printed circuit board 2195 to the extension member 2223b, and the connection module 2280 may partially overlap the printed circuit board 2195.

The connection module 2280 of the third embodiment of the present disclosure may include a filling layer 2281, and the plurality of connection lines 2285 disposed in the filling layer 2281.

An insertion space IS, into which the connection module 2280 is fitted and inserted, may be provided in the rear surface of the pressing plate 2223c. In addition, the insertion space IS may partially overlap the second accommodation groove 2283. That is, a part of the insertion space IS may constitute the second accommodation groove 2283.

Meanwhile, the connection line 2285 of the third embodiment of the present disclosure may connect the display panel 110 and the printed circuit board 2195.

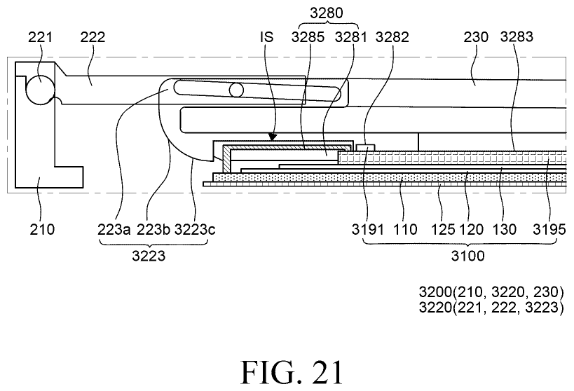

FIG. 21 is a cross-sectional view of a display device according to a fourth embodiment of the present disclosure.

The fourth embodiment in FIG. 21 is substantially identical in configuration to the above-mentioned first embodiment illustrated in FIGS. 1 to 17, except for a connection relationship between the circuit components using a connection module 3280. Therefore, repeated descriptions of the identical components will be omitted. Hereinafter, the components denoted by the same reference numerals will be described with reference to FIGS. 1 to 20.

With reference to FIG. 21, the display device of the fourth embodiment of the present disclosure may broadly include a display module 3100 and fixing devices 3200.

The display module 3100 may further include the display panel 110, the encapsulation part 120 configured to cover one surface of the display panel 110, and the heat dissipation plate 130 disposed above the encapsulation part 120.

The polarizing plate 125 may be disposed below the display panel 110.

In the fourth embodiment of the present disclosure, a drive IC 3191 may be mounted on a printed circuit board 3195. Therefore, the COF may be excluded, unlike the above-mentioned first and second embodiments.

The printed circuit board 3195 may be disposed above the heat dissipation plate 130. In the fourth embodiment of the present disclosure, because the COF is excluded, the printed circuit board 3195 may be disposed to be closer to the end of the display panel 110, in comparison with the above-mentioned first and second embodiments.

As described above, the fixing device 3200 may include the side frame 210, a fixation part 3220, and the buckling suppression part 230. A pressing member 3223 may include the coupling member 223a, the extension member 223b, and a pressing plate 3223c.

According to the fourth embodiment of the present disclosure, the drive IC 3191 and the printed circuit board 3195 may be accommodated in the fixation part 3220 and coupled to the side frame 210. To this end, a first accommodation groove 3282 configured to accommodate the drive IC 3191 and the second accommodation groove 3283 configured to accommodate the printed circuit board 3195 may be provided in the rear surface of the pressing member 3223 according to the fourth embodiment of the present disclosure. For example, the first accommodation groove 3282 may be positioned above the second accommodation groove 3283.

The first accommodation groove 3282 may have an accommodation space having a shape corresponding to the drive IC 3191, and the second accommodation groove 3283 may have an accommodation space having a shape corresponding to the printed circuit board 3195. That is, for example, the first accommodation groove 3282 may have an accommodation space having a depth and an area corresponding to a height and an area of the drive IC 3191, and the second accommodation groove 3283 may have an accommodation space having a depth and an area corresponding to a height and an area of the printed circuit board 3195.

Meanwhile, the connection module 3280, in which a plurality of connection lines 3285 are mounted, may be inserted into the rear surface of the pressing plate 3223c. For example, the connection module 3280 of the fourth embodiment may be positioned to be close to an extension member 3223b than the printed circuit board 3195 to the extension member 3223b, and the connection module 3280 may partially overlap the printed circuit board 3195.

The connection module 3280 of the fourth embodiment of the present disclosure may include a filling layer 3281, and the plurality of connection lines 3285 disposed in the filling layer 3281.

An insertion space IS, into which the connection module 3280 is fitted and inserted, may be provided in the rear surface of the pressing plate 3223c. In addition, the insertion space IS may partially overlap the second accommodation groove 3283. That is, a part of the insertion space IS may constitute the second accommodation groove 3283. However, the present disclosure is not limited thereto. The insertion space IS may partially overlap the first accommodation groove 3282 and the second accommodation groove 3283. In this case, a part of the insertion space IS may constitute the first accommodation groove 3282 and the second accommodation groove 3283.

Meanwhile, the connection line 3285 of the fourth embodiment of the present disclosure may connect the display panel 110 and the printed circuit board 3195.

The exemplary embodiments of the present disclosure can also be described as follows:

According to an aspect of the present disclosure, there is provided a display device. The display device includes a display module a side frame configured to support a part of a lateral portion of the display module, at least one fixation part coupled to the side frame and configured to press one surface of the display module and fix the display module to the side frame and a connection module inserted into a rear surface of the fixation part and being provided with a plurality of connection lines configured to connect components of the display module.

The fixation part may comprise a holder frame coupled to the side frame, a holder rod coupled to the holder frame and a pressing member coupled to the holder rod and configured to press one surface of the display module.

The pressing member may comprise a coupling member having a guide hole provided in a lateral portion thereof, the coupling member being configured to move along an inclination of the guide hole when an external force is applied to the pressing member, an extension member extending from one end of the coupling member in a direction in which the display module is positioned and a pressing plate extending perpendicularly from an extending end of the extension member and configured to selectively press the display module in accordance with a change in position, and the connection module is inserted into a rear surface of the pressing plate.

The connection module may comprise a bottom surface and sidewalls perpendicularly extending from the bottom surface.

The sidewall adjacent to the side frame among the sidewalls may constitute a guide portion inclined inward, the sidewall opposite to the guide portion among the sidewalls may constitute an elastic portion, and an elastic member may be interposed between the elastic portion and the pressing plate.

The connection module may comprise a filling layer and the plurality of connection lines disposed in the filling layer.

The connection lines may comprise wiring portions arranged side by side in one direction and contact portions extending from ends of the wiring portions in a perpendicular direction.

The filling layer may be made of resin and comprises a first filling layer positioned relatively inward based on the connection line, and a second filling layer positioned relatively outward based on the connection line, and the first filling layer and the second filling layer may be configured to surround the connection line, except for an end of the contact portion.

The display module may comprise a display panel, an encapsulation part configured to cover one surface of the display panel, a heat dissipation plate disposed above the encapsulation part; a chip-on-film (COF) disposed above the heat dissipation plate and a drive integrated circuit (IC) mounted on the COF.

The display module further may comprise a printed circuit board disposed above the heat dissipation plate and spaced apart from the COF.

The connection line may connect a pad of the display panel and an output pad of the COF.

The connection line may connect the COF and the printed circuit board.

The display device may further comprise a first accommodation groove provided in the rear surface of the pressing plate and configured to accommodate the drive IC and a second accommodation groove configured to accommodate the printed circuit board.

The display module may comprise a display panel, a drive IC mounted on the display panel; an encapsulation part configured to cover one surface of the display panel, except for the drive IC and a heat dissipation plate disposed above the encapsulation part.

The display module may further comprise a printed circuit board disposed above the heat dissipation plate.

The connection line may connect the display panel and the printed circuit board.

The display module may comprise a display panel, an encapsulation part configured to cover one surface of the display panel, except for a drive IC, a heat dissipation plate disposed above the encapsulation part, a printed circuit board disposed above the heat dissipation plate and the drive IC mounted on the printed circuit board.

The connection line may connect the display panel and the printed circuit board.

The plurality of connection lines may comprise a plurality of first connection lines and a plurality of second connection lines having different lengths, the first connection lines may comprise first wiring portions arranged side by side in one direction and first contact portions extending from ends of the first wiring portions in a perpendicular direction, and the second connection lines may comprise second wiring portions arranged side by side in one direction; and second contact portions extending from ends of the second wiring portions in a perpendicular direction.

The first wiring portion may have a longer length than the second wiring portion, and the second contact portion may have a longer length than the first contact portion.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure.

The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display module including a lateral portion;
a side frame configured to support a part of the lateral portion of the display module;
at least one fixation part coupled to the side frame and configured to press one surface of the display module and fix the display module to the side frame; and
a connection module inserted into a rear surface of the fixation part and being provided with a plurality of connection lines configured to couple components of the display module.

2. The display device of claim 1, wherein the fixation part comprises:
a holder frame coupled to the side frame;
a holder rod coupled to the holder frame; and
a pressing member coupled to the holder rod and configured to press one surface of the display module.

3. The display device of claim 2, wherein the pressing member comprises:
a coupling member having a guide hole provided in a lateral portion thereof, the coupling member being configured to move along an inclination of the guide hole when an external force is applied to the pressing member;
an extension member extending from one end of the coupling member in a direction in which the display module is positioned; and
a pressing plate extending perpendicularly from an extending end of the extension member and configured to selectively press the display module in accordance with a change in position, and
wherein the connection module is inserted into a rear surface of the pressing plate.

4. The display device of claim 3, wherein the connection module comprises:
a bottom surface; and
sidewalls perpendicularly extending from the bottom surface.

5. The display device of claim 4, wherein the sidewall adjacent to the side frame among the sidewalls constitutes a guide portion inclined inward,
wherein the sidewall opposite the guide portion among the sidewalls constitutes an elastic portion, and
wherein an elastic member is interposed between the elastic portion and the pressing plate.

6. The display device of claim 1, wherein the connection module comprises:
a filling layer; and
the plurality of connection lines disposed in the filling layer.

7. The display device of claim 6, wherein the connection lines comprise:
wiring portions arranged side by side in one direction; and
contact portions extending from ends of the wiring portions in a perpendicular direction.

8. The display device of claim 7, wherein the filling layer is made of resin and comprises a first filling layer positioned relatively inward based on the connection line, and a second filling layer positioned relatively outward based on the connection line, and
wherein the first filling layer and the second filling layer are configured to surround the connection line, except for an end of the contact portion.

9. The display device of claim 3, wherein the display module comprises:
a display panel;
an encapsulation part configured to cover one surface of the display panel;
a heat dissipation plate disposed above the encapsulation part;
a chip-on-film (COF) disposed above the heat dissipation plate; and
a drive integrated circuit (IC) mounted on the COF.

10. The display device of claim 9, wherein the display module further comprises a printed circuit board disposed above the heat dissipation plate and spaced apart from the COF.

11. The display device of claim 9, wherein the connection line couples a pad of the display panel and an output pad of the COF.

12. The display device of claim 10, wherein the connection line couples the COF and the printed circuit board.

13. The display device of claim 10, further comprising:
a first accommodation groove provided in the rear surface of the pressing plate and configured to accommodate the drive IC; and
a second accommodation groove configured to accommodate the printed circuit board.

14. The display device of claim 3, wherein the display module comprises:
a display panel;
a drive IC mounted on the display panel;
an encapsulation part configured to cover one surface of the display panel, except for the drive IC; and
a heat dissipation plate disposed above the encapsulation part.

15. The display device of claim 14, wherein the display module further comprises a printed circuit board disposed above the heat dissipation plate, and
wherein the connection line couples the display panel and the printed circuit board.

16. The display device of claim 3, wherein the display module comprises:
a display panel;
an encapsulation part configured to cover one surface of the display panel, except for a drive IC;
a heat dissipation plate disposed above the encapsulation part;
a printed circuit board disposed above the heat dissipation plate; and
the drive IC mounted on the printed circuit board,
wherein the connection line couples the display panel and the printed circuit board.

17. The display device of claim 1, wherein the plurality of connection lines comprises a plurality of first connection lines and a plurality of second connection lines having different lengths,
wherein the first connection lines comprise:
first wiring portions arranged side by side in one direction; and
first contact portions extending from ends of the first wiring portions in a perpendicular direction, and
wherein the second connection lines comprise:
second wiring portions arranged side by side in one direction; and
second contact portions extending from ends of the second wiring portions in a perpendicular direction.

18. The display device of claim 17, wherein the first wiring portion has a longer length than the second wiring portion, and the second contact portion has a longer length than the first contact portion.

19. The display device of claim 1, further comprising a buckling suppression part configured to apply pressure to a central portion of the fixation part to prevent deformation of the display module.

20. The display device of claim 7, wherein at least one contact portion is inclined or curved, and
wherein, in operation, enhances electrical connectivity under mechanical pressure.
